(19) United States
(12) Patent Application Publication
(10) Pub. No.: US 2012/0074523 A1
(43) Pub. Date: Mar. 29, 2012

(54) CONTROLLING MICROELECTRONIC SUBSTRATE BOWING

(76) Inventor: Michael Goldstein, Sunnyvale, CA (US)

(21) Appl. No.: 12/888,581

(22) Filed: Sep. 23, 2010

(51) Int. Cl. H01L 29/06; C30B 25/18

(52) U.S. Cl. 257/607; 117/88; 257/E29.005

(57) ABSTRACT

The present disclosure relates to the field of epitaxial structures for microelectronic device formation, particularly to heavily doped, substrates having a compensation component embedded along the dopant to prevent bowing of the substrate during deposition of an epitaxial layer.

### BACKGROUND

Embodiments of the present description generally relate to the field of fabricating microelectronic substrates, such as silicon wafers, and, more particularly, to a controlling bowing in a microelectronic substrates that may occur during epitaxial layer deposition.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIGS. 1 and 2 illustrates a oblique and a top plan view, respectively, of a substrate.

FIG. 3 illustrates an epitaxial layer deposited on the substrate of FIGS. 1 and 2 to form an epitaxial structure.

FIGS. 4a and 4b illustrate epitaxial structure bowing on differing substrate sizes.

FIG. 5 is a graph illustrating bowing of an epitaxial structure as a function of substrate diameter for a specific epitaxial layer thickness.

FIG. 6 is a graph illustrating germanium and boron concentrations changing during crystal growth of an ingot from which a substrate is formed.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

Embodiments of the present description relate to the field of epitaxial structures for microelectronic device formation, particularly to heavily doped, substrates having a compensation component embedded along the dopant to prevent bowing of the substrate during deposition of an epitaxial layer.

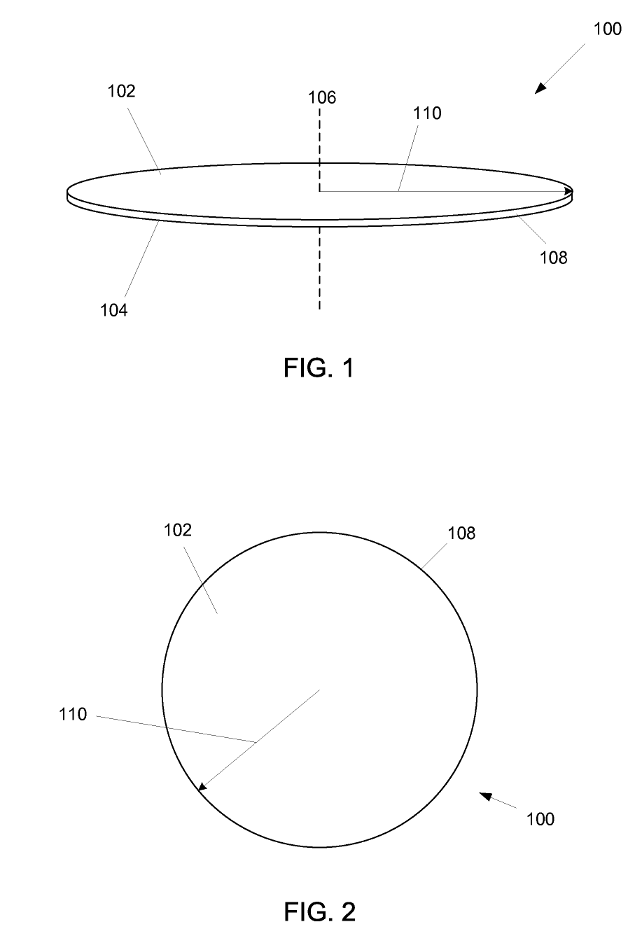

FIGS. 1 and 2 illustrate a substrate 100, such as a moncrystalline silicon wafer, that is heavily doped with an N-type dopant (N++) or a P-type dopant (P++). The substrate 100 is the starting material for many processes in the manufacture of microelectronic devices, and is commonly fabricated with the Czochralski process, where a single seed crystal is immersed into molten material, such as silicon, and then grown by extraction. The substrate 100 is then sliced from the resulting single crystal ingot. A dopant component can be added to the molten material in order to dope the silicon to change its electrical properties. The substrate 100 can be doped with one or more N-type or P-type dopants. Typical N-type dopants may include, but are not limited to, phosphorous, arsenic, and antimony. Typical P-type dopants may include, but are not limited to, boron, aluminum, and gallium. The electrical properties imparted by these dopants in the silicon are well known in the art.

The substrate 100 may have a front surface 102, a back surface 104, a central axis 106 which is substantially perpendicular to the substrate front surface 102 and the substrate back surface 104, a circumferential edge 108 extending between the substrate front surface 102 and the substrate back surface 104, and a radius 110 extending from the substrate central axis 106 to the substrate circumferential edge 108.

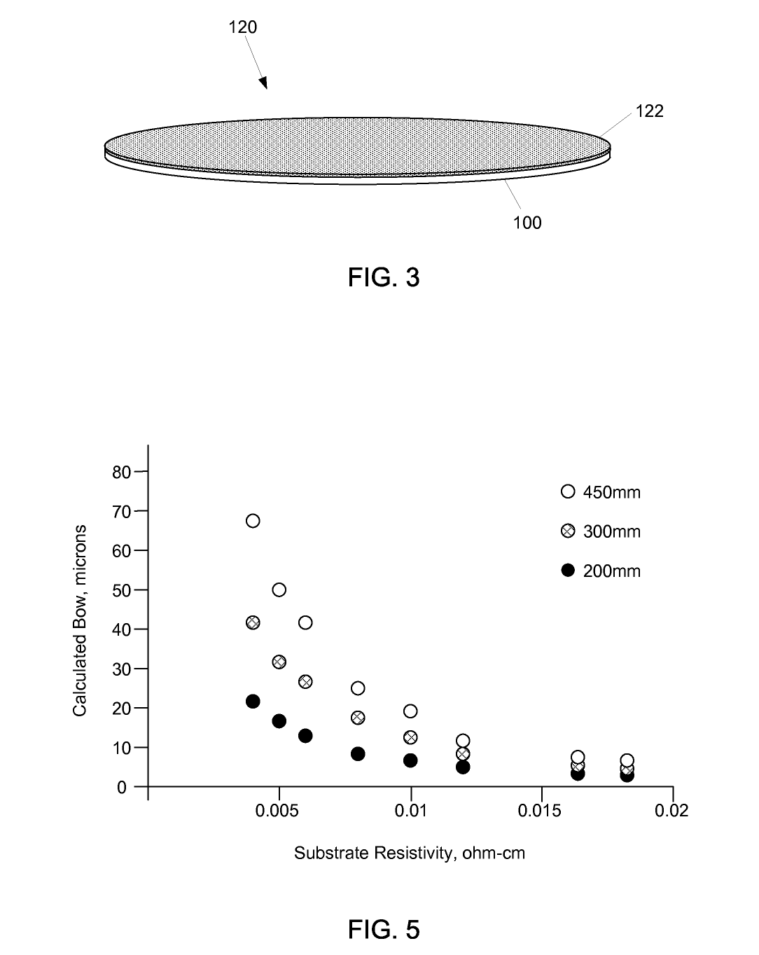

An epitaxial layer 122 may be deposited, such as by chemical vapor deposition, on the substrate front surface 102 (see FIGS. 1 and 2) to form an epitaxial structure 120, as shown in FIG. 3. The epitaxial layer 122 may be a moncrystalline film, such as silicon, wherein the substrate 100 acts as a seed crystal and the deposited epitaxial layer 122 takes on the lattice structure and orientation of the substrate 100. The epitaxial layer 122 may be lightly doped with an N-type dopant or a P-type dopant, as will be understood to those skilled in the art.

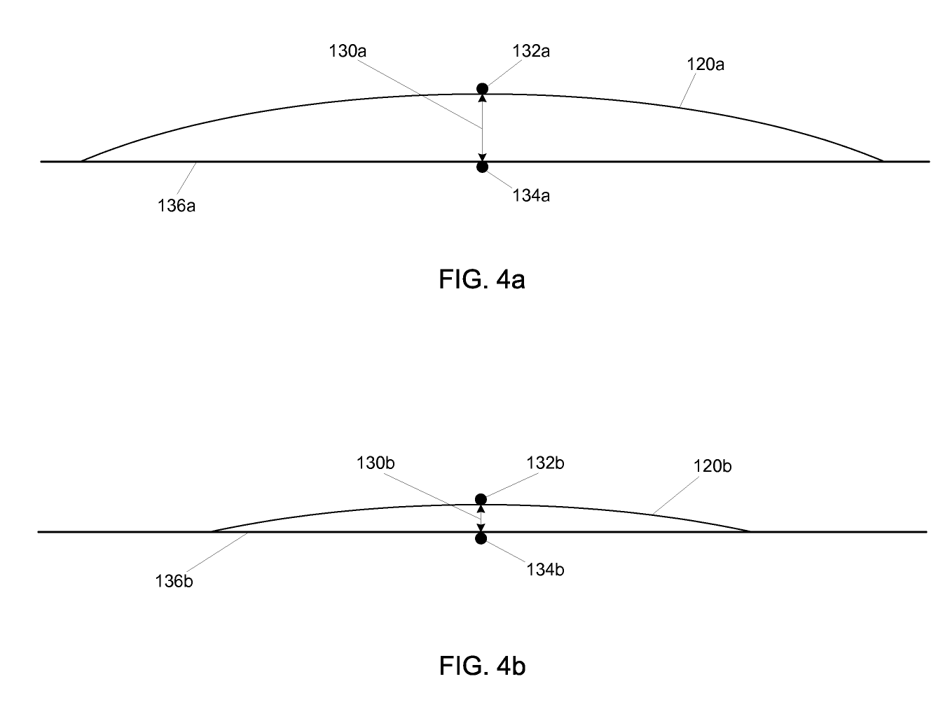

The deposition of the epitaxial layer 122 may cause the epitaxial structure 120 to “bow” due to a lattice constant mismatch between the epitaxial layer 122 and the substrate 100. FIGS. 4a and 4b show a relative size difference between a 450 mm diameter substrate and a 300 mm diameter substrate, respectively. As shown in FIGS. 4a and 4b, the “bow” is a deviation 130a and 130b of a center point 132a and 132b (e.g. the point at which the substrate central axis 106, as shown in FIG. 1, intersects the epitaxial structure 120) of a free, unclamped epitaxial structure 120a and 120b from a median reference point 134a and 134b on a reference plane 136a and 136b, respectively. If the bow or deviation 130a or 130b is severe enough some fabrication equipment may not be able to handle the epitaxial structures 120, 120a, or 120b. As it can be seen in comparing FIGS. 4a and 4b, bowing becomes a more serious problem as size or diameter of the epitaxial structure 120a and 120b, respectively, increases.

In one example, where a heavily doped silicon substrate is doped with boron, the lattice constant of the substrate decreases due to the difference in the covalent radius between silicon (about 1.17 Å) and boron (about 0.88 Å). In other words, boron atoms are smaller than silicon atoms causing shrinkage of the silicon lattice, which may cause the substrate to bow. The lattice constant “a” relationship to boron concentration is (in Angstroms):

a[B]=1.17−(1.17−0.88)×[B]/[Si]

where: [B] is the Boron concentration in atoms·cm⁻³ and [Si] is 5×10²² cm⁻³

The bow of the epitaxial structure 120 due to lattice mismatch is (in cm):

Bow={3×t_{EPI}×r²E}/t²_{SUB}

where:

t_{EPI} is the epitaxial layer thickness

r is the substrate radius

t_{SUB} is the substrate thickness

E={a(a_{(Epi)}−a_{(Sub)}}/a_{(Sub)}
where:
   a_{(Epi)} is the lattice constant of the epitaxial layer
   and
   a_{(Sub)} is the lattice constant of the substrate

FIG. 5 illustrates the calculated bow in microns (y-axis) of an epitaxial structure 120 as a function of substrate resistivity in ohm·cm (x-axis) for three different substrate diameters (i.e. 450 mm, 300 mm, and 200 mm). The epitaxial layer 122 is about 3 microns. The substrate 100 thickness is 775 microns. It is understood that the resistivity is inversely proportional to the dopant concentration, as is known to those skilled in the art. For a heavily boron doped silicon substrate, the resistivity would be between about 0.005 and 0.01 ohm·cm. In this resistivity region, the substrate bowing is considerable, and the lower the resistivity (i.e. higher the dopant concentration), the greater the bowing, as shown the FIG. 5.

As the industry moves to larger size/diameter substrates, the current options for reducing bowing are to reduce the thickness of the epitaxial layer 122 or to increase the resistivity of the substrate 100, neither of which may be desired.

In an embodiment of the present description, the substrate 100 is co-doped with a dopant and a compensation component. The compensation component acts to adjust the lattice mismatch between the substrate 100 and the epitaxial layer 122, which reduces or substantially eliminates bowing of the epitaxial structure 120. In one embodiment, the compensation component may be incorporated into the substrate 100 at the same time as the dopant is incorporated during the formation of the substrate ingot, as previously discussed. When the dopant atoms are smaller than substrate atoms, then the compensation component will have atoms larger than substrate atoms. When the dopant atoms are larger than substrate atoms, then the compensation component will have atoms smaller than substrate atoms. Thus, the substrate may be tuned with the addition of the compensation component to have a lattice constant that is substantially the same as that of a selected epitaxial layer, which reduces or substantially eliminates post epitaxial layer strain.

In one embodiment, the substrate may comprise silicon, the dopant may be boron, and the compensation component may be a group IV atom, such as germanium and tin, which are larger than boron atoms to compensate for lattice shrink caused by the boron.

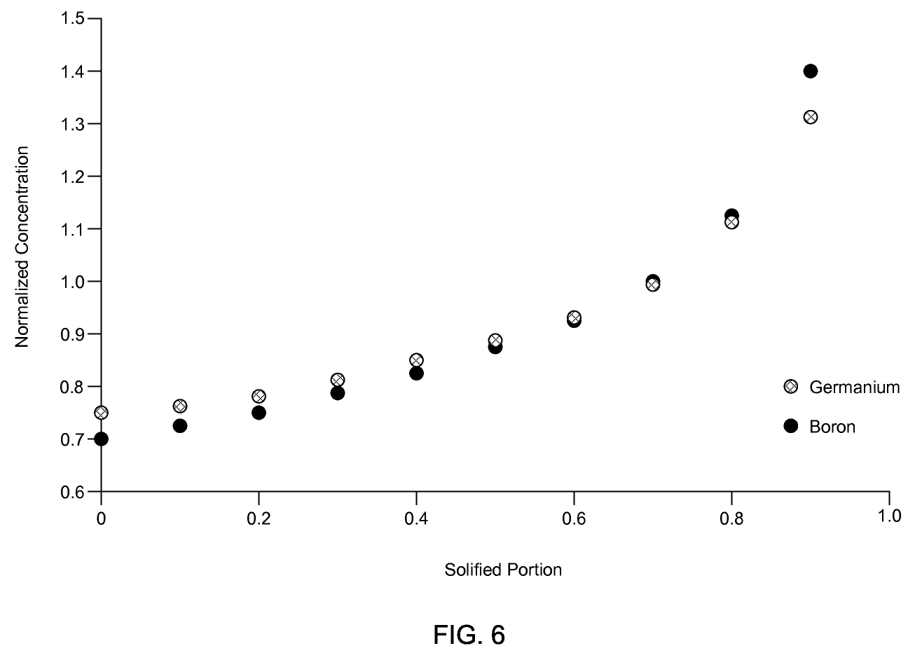

In a specific embodiment, the substrate may comprise silicon, the dopant may be boron, and the compensation component may be germanium. Germanium atoms have a covalent radius of about 1.22 Å, which will compensate for a smaller boron atom covalent radius of 0.88 Å. In one embodiment, the concentration level of the germanium may be about 5 grams per 1 kilogram of silicon for a substrate resistivity between about 0.005 and 0.01 ohm·cm. For germanium doping, the segregation coefficient is about 0.7, which is very similar to the boron segregation coefficient. Therefore, the germanium and boron concentrations may change in a similar manner during the crystal growth as shown in FIG. 6, so that the bowing in the epitaxial substructure becomes decoupled from the substrate resistivity, as will be understood to those skilled in the art.

In another embodiment, the substrate may comprise silicon, the dopant may be boron, and the compensation component may be tin. Tin atoms have a covalent radius of about 1.41 Å, which will compensate for the smaller boron atom covalent radius of 0.88 Å. In an embodiment, the concentration level of the tin may be about 1 gram per 1 kilogram of silicon for a substrate resistivity between about 0.005 and 0.01 ohm·cm.

Unless explicitly noted otherwise, reference to the heavily doped substrates as “N++” or “P++” is understood to also refer to substrates having doping levels conventionally referred to as N+ and N+++ or P+ and P+++, respectively. Furthermore, unless explicitly noted otherwise, reference to the lightly doped epitaxial layer as “N” or “P” should be understood to also refer to substrates having doping levels conventionally referred to as N- or P-, respectively.

It is also understood that the subject matter of the present description is not necessarily limited to specific embodiments described. The subject matter may be applied to other heavily doped substrate applications. Furthermore, the subject matter may also be used in any appropriate application outside of the microelectronic device fabrication field, as will be understood to those skilled in the art.

The detailed description has described various embodiments of the devices and/or processes through the use of illustrations, block diagrams, flowcharts, and/or examples. Insofar as such illustrations, block diagrams, flowcharts, and/or examples contain one or more functions and/or operations, it will be understood by those skilled in the art that each function and/or operation within each illustration, block diagram, flowchart, and/or example can be implemented, individually and/or collectively, by a wide range of hardware, software, firmware, or virtually any combination thereof.

The described subject matter sometimes illustrates different components contained within, or connected with, different other components. It is understood that such illustrations are merely exemplary, and that many alternate structures can be implemented to achieve the same functionality. In a conceptual sense, any arrangement of components to achieve the same functionality is effectively “associated” such that the desired functionality is achieved. Thus, any two components herein combined to achieve a particular functionality can be seen as “associated with” each other such that the desired functionality is achieved, irrespective of structures or intermediate components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

It will be understood by those skilled in the art that terms used herein, and especially in the appended claims are generally intended as “open” terms. In general, the terms “including” or “includes” should be interpreted as “including but not limited to” or “includes but is not limited to”, respectively. Additionally, the term “having” should be interpreted as “having at least”.

The use of plural and/or singular terms within the detailed description can be translated from the plural to the singular and/or from the singular to the plural as is appropriate to the context and/or the application.

It will be further understood by those skilled in the art that if an indication of the number of elements is used in a claim, the intent for the claim to be so limited will be explicitly recited in the claim, and in the absence of such recitation no such intent is present. Additionally, if a specific number of an introduced claim recitation is explicitly recited, those skilled in the art will recognize that such recitation should typically be interpreted to mean “at least” the recited number.

The use of the terms “an embodiment,” “one embodiment,” “some embodiments,” “another embodiment,” or “other embodiments” in the specification may mean that a particular feature, structure, or characteristic described in connection with one or more embodiments may be included in at least some embodiments, but not necessarily in all embodiments. The various uses of the terms “an embodiment,” “one embodiment,” “another embodiment,” or “other embodiments” in the detailed description are not necessarily all referring to the same embodiments.

While certain exemplary techniques have been described and shown herein using various methods and systems, it should be understood by those skilled in the art that various other modifications may be made, and equivalents may be substituted, without departing from claimed subject matter or spirit thereof. Additionally, many modifications may be made to adapt a particular situation to the teachings of claimed subject matter without departing from the central concept described herein. Therefore, it is intended that claimed subject matter not be limited to the particular examples disclosed, but that such claimed subject matter also may include all implementations falling within the scope of the appended claims, and equivalents thereof.

What is claimed is:

1. An epitaxial structure comprising:
a substrate including a dopant and a compensation component, and
an epitaxial layer formed on the substrate.

2. The epitaxial structure of claim 1, wherein the substrate and the epitaxial layer have substantially the same lattice constant.

3. The epitaxial structure of claim 1, wherein the dopant is boron.

4. The epitaxial structure of claim 1, wherein the compensation component is germanium.

5. The epitaxial structure of claim 1, wherein the compensation component is tin.

6. The epitaxial structure of claim 1, wherein the substrate comprises silicon having a boron dopant and a germanium compensation component.

7. The epitaxial structure of claim 6, wherein the germanium compensation component has a concentration of about 5 grams per 1 kilogram of silicon.

8. The epitaxial structure of claim 1, wherein the substrate comprise silicon having a boron dopant and a tin compensation component.

9. The epitaxial structure of claim 8, wherein the tin compensation component has a concentration of about 1 gram per 1 kilogram of silicon.

10. A method of forming epitaxial structure comprising:
providing a substrate including a dopant and a compensation component, and
forming an epitaxial layer on the substrate.

11. The method of claim 10, wherein providing a substrate comprises providing a substrate having substantially the same lattice constant as the epitaxial layer.

12. The method of claim 11, wherein providing a substrate having substantially the same lattice constant as the epitaxial layer comprises providing a substrate having substantially the same lattice constant as the epitaxial layer, wherein the compensation component alters the lattice constant of the substrate to be substantially the same lattice constant as the epitaxial layer.

13. The method of claim 10, wherein providing a substrate including a dopant and a compensation component comprises providing a substrate including a boron dopant and a compensation component.

14. The method of claim 10, wherein providing a substrate including a dopant and a compensation component comprises providing a substrate including a dopant and a germanium compensation component.

15. The method of claim 10, wherein providing a substrate including a dopant and a compensation component comprises providing a substrate including a dopant and a tin compensation component.

16. The method of claim 1, wherein providing a substrate including a dopant and a compensation component comprises providing a silicon substrate including a boron dopant and a germanium compensation component.

17. The method of claim 16, wherein providing a silicon substrate including a boron dopant and a germanium compensation component comprises providing a silicon substrate including a boron dopant and a germanium compensation component at concentration of about 5 grams per 1 kilogram of silicon.

18. The method of claim 10, wherein providing a substrate including a dopant and a compensation component comprises providing a silicon substrate including a boron dopant and a tin compensation component.

19. The method of claim 18, wherein providing a silicon substrate including a boron dopant and a tin compensation component comprises providing a silicon substrate including a boron dopant and a tin compensation component at concentration of about 1 gram per 1 kilogram of silicon.
